(19) United States
(12) Patent Application Publication
(10) Pub. No.: US 2009/0027845 A1
(43) Pub. Date: Jan. 29, 2009

(54) Connector with build-in control unit and its application

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/007,271

(22) Filed: Jan. 9, 2008

(30) Foreign Application Priority Data
Jul. 26, 2007 (TW) 96127175

(51) Int. Cl. H05K 7/00

(52) U.S. Cl. 361/684

(57) ABSTRACT

A connector with a build-in control unit is to be suitable for use in a memory package. The connector includes a main body; a control unit; a plurality of first external contacts; and a plurality of second external contacts. The control unit is arranged in the main body. The first external contacts and the second external terminals are respectively arranged at the surface of the main body and electrically connected to the control unit. Wherein, the first external contacts are used for electrically connecting with the memory package. The I/O signal format of the memory package can transferred into the required I/O signal format by the control unit of the connector of the present invention.

### BACKGROUND OF THE INVENTION

1. Field of the Invention

The present invention relates to a connector with a build-in control unit. More particularly, the present invention relates to a connector with a build-in control unit to apply to the memory package.

2. Description of the Prior Art

Because of the development and progress of the science and technology, the memory card is used in various electronic product, such as the personal computer, the cell phone, the digital camera, the digital Video, and the personal digital assistant and etc al. Usually, the memory card provides with at least one memory package having the memory chip. Owing to the widely use of 3C products, the capacity of the memory card is continuously increasing to the high capacity, such as 32G, 64G, or 128G.

However, different capacity or type of the memory card may have the different format of the I/O signal. Hence, the electronic products need to update the tool to match the format of different memory card. Once the new memory card with high capacity is developed, the electronic products may amend and update for matching the format of the I/O signal of the new memory card and the former electronic products can not be used because of the compatibility problem.

### SUMMARY OF THE INVENTION

One object of the present invention is to provide a connector with a build-in control unit and its application. The control unit build-in the connector can transfer the format of the I/O signal of the memory package into a required format of the I/O signal so as to effectively enhance the compatibility of the memory package.

In accordance with the above object of the present invention, a connector with a build-in control unit is provided. The connector includes: a main body; a control unit arranged at the main body; a plurality of first external contacts arranged at the surface of the main body and electrically connect with the control unit, wherein those first external contacts are used for electrically connecting with at least one the memory package; and a plurality of second external contacts arranged at the surface of the main body and electrically connecting with the control unit.

Another embodiment of the present invention provides a memory package structure which is using the connector with a build-in control unit. The memory package structure includes: the connector mentioned above; a first memory package arranged on the main body of the connector; and a first electrically connecting structure to electrically connect the first memory package and those first external contacts of the connector.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram in accordance with one embodiment of the present invention;

FIG. 2 is a schematic diagram in accordance with one embodiment of the present invention;

FIG. 3A and FIG. 3B are schematic diagrams in accordance with different embodiments of the present invention; and

FIG. 4A, FIG. 4B and FIG. 4C are schematic diagrams in accordance with different embodiments of the present invention.

### DETAILED DESCRIPTION OF THE INVENTION

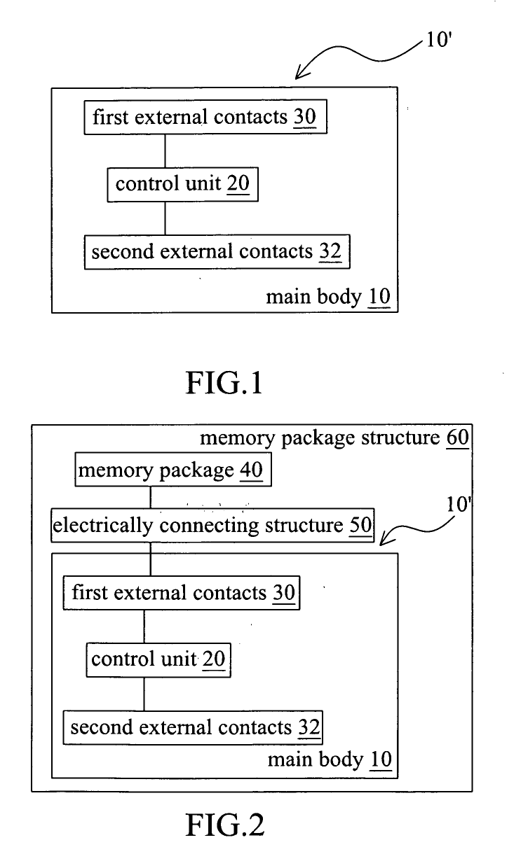

Referring to FIG. 1, in one embodiment, a connector 10′ includes: a main body 10, a control unit 20, a plurality of first external contacts 30, and a plurality of second external contacts 32. The control unit 10 is arranged at the main body 10. First external contacts 30 and second external contacts 32 are respectively arranged at the surface of the main body 10 and electrically connecting with the control unit 20. Wherein, first external contacts 30 are used for electrically connecting with at least one memory package (not shown in FIG. 1).

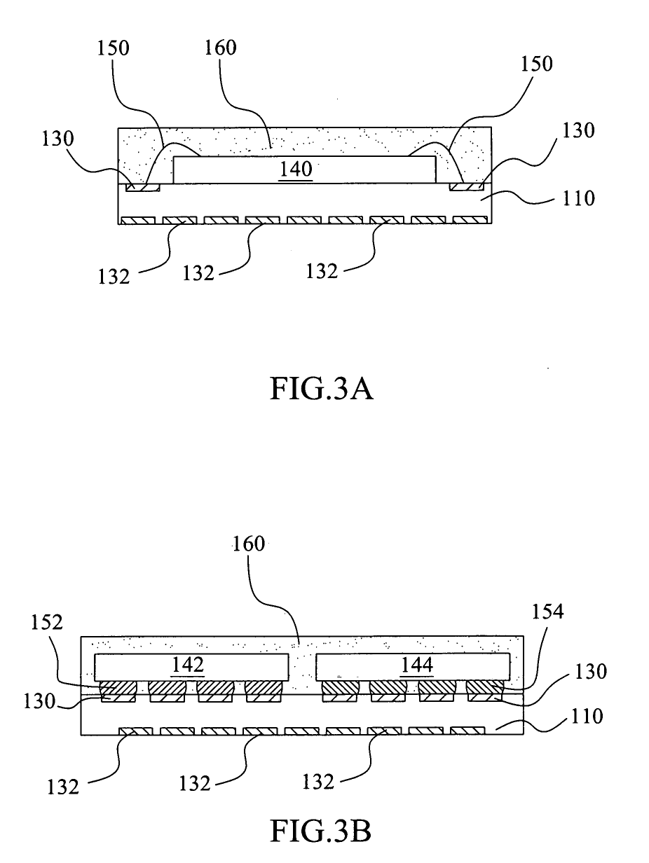

Following the above description and referring to FIG. 2, in one embodiment, a memory package structure 60 includes a connector 10′, a memory package 40, and a electrically connecting structure 50. The memory package 40 is arranged on the main body 10 of the connector 10′ and electrically connecting with first external contacts 30 via a first electrically connecting structure 50. In the memory package structure 60, the I/O signal of the memory structure 40 will be transferred into the required format via the control unit 20 build-in the connector 10′. Then, the transferred I/O signal can be output via second external contacts 32.

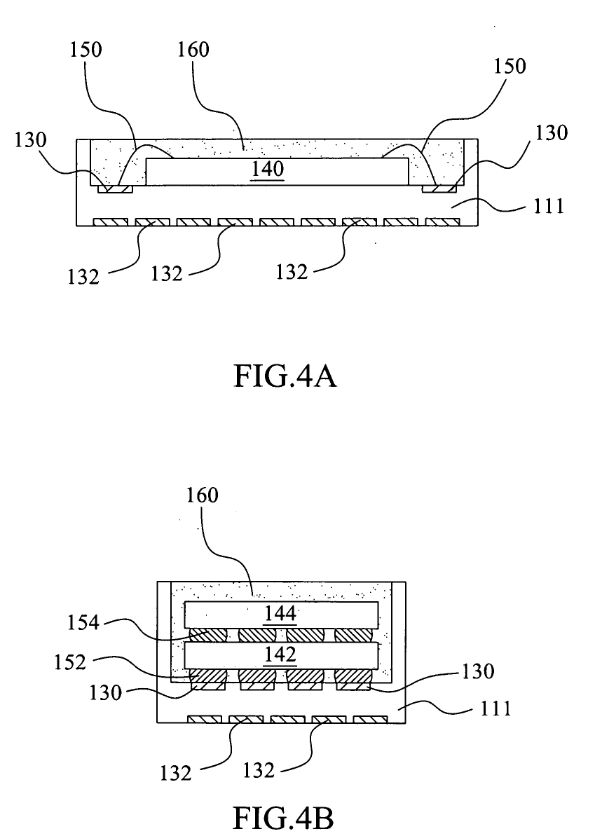

Next, such as shown in FIG. 3A, in one embodiment, the main body of the connector is a printed circuit board 110. A plurality of first external contacts 130 and a plurality of second external contacts 132 are respectively arranged at different surface of the printed circuit board 110. First external contacts 130 and second external contacts 132 are electrically connecting with the control unit (not shown in FIG. 3A). The control unit can be a control circuit or a control chip arranged on the printed circuit board 110.

Following the above description, a first memory package 140 is arranged on the printed circuit board 110 and utilizes a first electrically connecting structure, such as a plurality of conductive wires 150 or conductive balls, to electrically connect with first external contacts 130. In one embodiment, an encapsulating component 160 is covering the first memory package 140 and conductive wires 150 to expose second external contacts 132 arranged on another surface of the printed circuit board 110.

Such as shown in FIG. 3B, in one embodiment, a first memory package 142 is arranged on the printed circuit board 110 and utilizes a first electrically connecting structure, such as a plurality of conductive wires or conductive balls 152, to electrically connect with partial first external contacts 130. Further, in the memory package structure, a second memory package 144 is arranged side-by-side with the first memory package 142 and utilizes a second electrically connecting structure, such as a plurality of conductive wires or conductive balls 154, to electrically connect with partial first external contacts 130. An encapsulating component 160 is covering the first memory package 142, the second memory package 144, conductive balls 152 and conductive balls 154 to expose second external contacts 132 arranged on another surface of the printed circuit board 110. In the present embodiment, the first memory package 142 and the second memory package 144 are side-by-side arranged. However, not shown in figures, the first memory package 142 and the second memory package 144 can be stacked with each other and are electrically connecting via conductive wires or conductive balls.

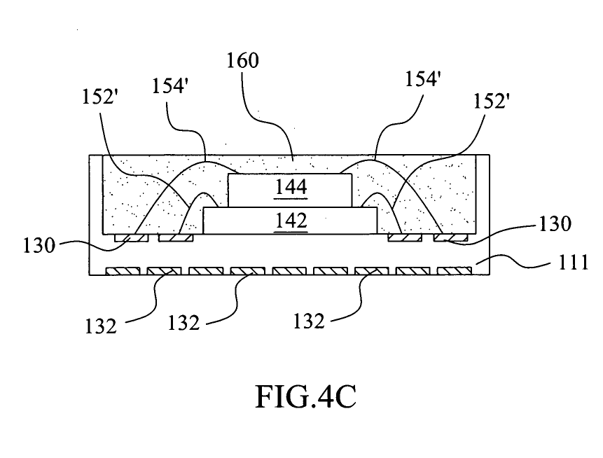

Referring to FIG. 4B, in one embodiment, the main body of the connector is a shell body 111. A plurality of first external contacts 130 and a plurality of second external contacts 132 are respectively arranged at different surface of the shell body 111. First external contacts 130 and second external contacts 132 are electrically connecting with the control unit (not shown in FIG. 4A). The control unit can be a control chip arranged in the shell body 111.

Following the above description, in one embodiment, a first memory package 140 is arranged on the shell body 110 and utilizes a first electrically connecting structure, such as a plurality of conductive wires 150 or conductive balls, to electrically connect with first external contacts 130. An encapsulating component 160 is inject into the shell body to cover the first memory package 140 and conductive wires 150 to expose second external contacts 132.

Next, referring to FIG. 4B, in one embodiment, a first memory package 142 and a second memory package 144 are stacked with each other in the shell body 111. The first memory package 142 utilizes a first electrically connecting structure, such as a plurality of conductive balls 152 and conductive wires, to electrically connect with first external contacts 130. Further, the second memory package 144 utilizes a second electrically connecting structure, such as a plurality of conductive wires or conductive balls 154, to electrically connect with the first memory package 142. An encapsulating component 160 is injecting into the shell body 111 to cover the first memory package 142, the second memory package 144, conductive balls 152 and conductive balls 154 to expose second external contacts 132.

Referring to FIG. 4C, in one embodiment, the first memory package 142 utilizes conductive wires 152′ to electrically connect with partial first external contacts 130. Further, a second memory package 144 is stacked on the first memory package 142 and utilizes conductive wires 154′ to electrically connect with partial first external contacts 130.

The present memory package structure can apply to the secure digital card (SD card), the mini SD card, the micro SD card, the multi media card (MMC card), the compact flash card (CF card), the dynamic random access memory (DRAM), the synchronous static random access memory (SSRAM) or the Nor flash memory.

To sum up the foregoing descriptions, the present invention provides a connector with a build-in control unit and its application. The control unit build-in the connector can transfer the format of the I/O signal of the memory package into a required format of the I/O signal so as to effectively enhance the compatibility of the memory package.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A connector which is suitable for use in a memory package, said connector comprising:
a main body;
a control unit arranged at said main body;
a plurality of first external contacts arranged at the surface of said main body and electrically connecting with said control unit, wherein those first external contacts are used for electrically connecting with at least one said memory package; and
a plurality of second external contacts arranged at the surface of said main body and electrically connecting with said control unit.

2. The connector according to claim 1, wherein said main body is a printed circuit board.

3. The connector according to claim 2, wherein those first external contacts and those second external contacts are respectively arranged at two surfaces of said printed circuit board.

4. The connector according to claim 2, wherein said control unit is a control circuit arranged on said printed circuit board.

5. The connector according to claim 2, wherein said control unit is a control chip arranged on said printed circuit board.

6. The connector according to claim 1, wherein said main body is a shell body.

7. The connector according to claim 6, wherein said control unit is a control chip arranged inside said shell body.

8. A memory package structure which is used the connector according to claim 1, said memory package structure comprising:
said connector;
a first memory package arranged on said main body of said connector; and
a first electrically connecting structure to electrically connect said first memory package and those first external contacts of said connector.

9. The memory package structure according to claim 8, further comprising a molding component to cover said first memory package and said first electrically connecting structure and to expose those second external contacts of said connector.

10. The memory package structure according to claim 8, wherein said first electrically connecting structure are a plurality of conductive wires or a plurality of conductive balls.

11. The memory package structure according to claim 8, further comprising a second memory package stacked and arranged on said first memory package, wherein said first memory package and said second memory package are electrically connecting with each other via a second electrically connecting structure.

12. The memory package structure according to claim 11, wherein said second electrically connecting structure are a plurality of conductive wires or a plurality of conductive balls.

13. The memory package structure according to claim 8, further comprising a second memory package stacked and arranged on said first memory package, wherein said second memory package is electrically connecting with partial those first external contacts via a second electrically connecting structure.

14. The memory package structure according to claim 13, wherein said second electrically connecting structure are a plurality of conductive wires.

15. The memory package structure according to claim 8, further comprising a second memory package arranged side-by-side with said first memory package on said main body, wherein said second memory package is electrically connecting with partial those first external contacts via a second electrically connecting structure.

16. The memory package structure according to claim 15, wherein said second electrically connecting structure are a plurality of conductive wires or a plurality of conductive balls.

17. The memory package structure according to claim 8 can apply to the secure digital card (SD card), the mini SD card, the micro SD card, the multi media card (MMC card), the compact flash card (CF card), the dynamic random access memory (DRAM), the synchronous static random access memory (SSRAM) or the Nor flash memory.
